(19) United States
(12) Patent Application Publication
(10) Pub. No.: US 2018/0077447 A1
(43) Pub. Date: Mar. 15, 2018

(54) DE-INTERLEAVING CIRCUIT AND DE-INTERLEAVING METHOD

(71) Applicant: MStar Semiconductor, Inc., Hsinchu Hsien (TW)

(72) Inventor: CHUN-CHIEH WANG, Hsinchu County (TW)

(21) Appl. No.: 15/695,345

(22) Filed: Sep. 5, 2017

(30) Foreign Application Priority Data
Sep. 12, 2016 (TW) 105129532

(51) Int. Cl. H04N 21/4385; H03M 13/27; H04N 21/44; H04N 21/426; H04N 21/6402

(52) U.S. Cl. CPC H04N 21/4385; H03M 13/2764; H04N 21/44004; H03M 13/2785; H04N 21/6402; H04N 21/42692; H03M 13/2735; H04N 21/426

(57) ABSTRACT

A de-interleaving circuit that performs a time de-interleaving process on an interleaved block of an interleave signal includes: an input buffer, buffering multiple information units included in a time interleaved block; a writing address generator, generating multiple writing addresses according to a predetermined rule to write the information units buffered in the input buffer to a memory; a reading address generator, generating multiple reading addresses according to the predetermined rule to read the information units from the memory; and an output buffer, buffering the information units read from the memory. The information units are stored in multiple tiles of the memory. The tiles correspond to multiple regions of the time interleaved block, the multiple regions include a first region and a second region, and the dimensions of each tile in the first region are different from the dimensions of each tile in the second region.

This application claims the benefit of Taiwan application Serial No. 105129532, filed Sep. 12, 2016, the subject matter of which is incorporated herein by reference.

### BACKGROUND OF THE INVENTION

### Field of the Invention

The invention relates in general to a time de-interleaving circuit and method, and more particularly to a time de-interleaving circuit and method capable of reducing the number of times of accessing a memory.

### Description of the Related Art

In general, before a Digital Video Broadcasting-Second Generation Terrestrial (DVB-T2) broadcast signal is transmitted, cell interleaving and time interleaving processes are performed on data to be transmitted to minimize effects that various types of interference has on transmitted data, so that the receiver may obtain correct transmitted data. After the signal is received at the receiver, time de-interleaving and cell de-interleaving processes are performed on the received signal to correctly decode the data. FIG. 1 shows a block diagram of a conventional signal receiver 100. The signal receiver 100 includes a demodulator 110, a frequency de-interleaving circuit 120, a time de-interleaving circuit 130, a cell de-interleaving circuit 140, a de-mapping circuit 150 and a decoding circuit 160. An input signal is a modulated signal (e.g., a quadrature amplitude modulation (QAM) signal based on orthogonal frequency division multiplexing (OFDM)), and is processed by the demodulator 110 to obtain an interleaved signal that includes information of two orthogonal components (I and Q) and a signal-to-noise ratio (SNR). After de-interleaving processes performed by the frequency de-interleaving circuit 120, the time de-interleaving circuit 130 and the cell de-interleaving circuit 140, the data is rearranged in a correct sequence. The processed data is then computed by de-mapping circuit 150 to restore into bit information, which is next processed (e.g., a low-density parity check (LPDC) and BCH decoding) by the decoding circuit 160 to obtain the transmitted data.

The time de-interleaving operation is performed in a unit of one time interleaved (TI) block. Each TI block includes N_{FEC} forward error correction (FEC) blocks, and each FEC block includes N_{cell} cells. When the receiver performs a time de-interleaving process, the size of a dynamic random access memory (DRAM) is set as Nᵣ rows and N_{c} columns, where Nᵣ is N_{cell}/5 and N_{c} is N_{FEC}×5. The time de-interleaving circuit 130 in FIG. 1 performs a de-interleaving process on the N_{FEC}×N_{cell} units included in the above TI block.

According to the information in the above description, a time de-interleaving process involves a tremendous amount of memory access operation, and the performance of time de-interleaving becomes higher as the efficiency of memory access gets higher. Based on the design of a common memory, the time needed for accessing N sets of data from the same row of a memory is apparently less than the time needed for accessing N sets of data from different rows of the memory. Therefore, to enhance memory access efficiency, a tile technology is adopted.

Refer to the description below for the tile technology. For example, assuming that the size of memory required by one TI block is 18 rows and 13 columns, and a time de-interleaving process writes data according to a first-direction sequence (e.g., the first-direction sequence is a vertical sequence in this example) as shown in FIG. 2a. More specifically, the 0^{th} set of written data to the 17^{th} set of written data form a 1^{st} vertical data group, the 18^{th} set of written data to the 35^{th} set of written data form a 2^{nd} vertical data group, . . . , and the 216^{th} set of written data to the 233^{rd} set of written data form a 13^{th} vertical data group. The time de-interleaving process further reads data according to a second-direction sequence (e.g., the second-direction sequence is a horizontal sequence in this example) as shown in FIG. 2b. More specifically, the 0^{th} set of read data to the 12^{th} set of read data (corresponding to the 0^{th}, 18^{th}, 36^{th}, . . . , 198^{th} and 216^{th} sets of written data in FIG. 2a) form a 1^{st} horizontal data group, the 13^{th} set of read data to the 25^{th} set of read data (corresponding to the 1^{st}, 19^{th}, 37^{th}, . . . , 199^{th}, and 217^{th} sets of written data in FIG. 2a) form a 2^{nd} horizontal data group, . . . , and the 221^{th} set of read data to the 233^{rd} set of read data (corresponding to the 17^{th}, 35^{th}, 53^{rd}, . . . , 215^{th} and 233^{rd} sets of written data in FIG. 2a) form an 18^{th} horizontal data group. If the size of the memory adopted by the above time de-interleaving process is 20 rows and 16 columns, in order to prevent spending a large amount of time due to row switching during the access, 16 storage units of the same row may be planned as a memory tile. Thus, the total number of memory tiles (i.e., Tile 0 to Tile 19, as shown in FIG. 3) needed for accessing the data in FIG. 2a and FIG. 2b is:

┌N_{c}/T_{c}┐×[Nᵣ/Tᵣ]=4×5=20

In the above equation, N_{c} is the number of vertical data groups (N_{c}=13 in this example), Nᵣ is the number of horizontal data groups (Nr=18 in this example), T_{c} is the vertical dimension of each tile (T_{c}=4 in this example), Tᵣ is the horizontal dimension each tile (Tᵣ=4 in this example), and the operation symbol ┌ ┐ represents rounding up to an integer function. As described, the written data stored in Tile 0 to Tile 19 in FIG. 3 is as shown in FIG. 4a, wherein the 0^{th} to 3^{rd} sets of written data is written to Tile 0, the 4^{th} to 7^{th} sets of written data is written to Tile 1, the 8^{th} to 11^{th} sets of written data is written to Tile 2, the 12^{th} to 15^{th} sets of written data is written to Tile 3, the 16^{th} and 17^{th} sets of written data is written to Tile 4, the 18^{th} to 21^{st} sets of written data is written to Tile 0, . . . , and the 232^{nd} and 233^{rd} sets of data is written to Tile 19. Thus, the total number of times of changing the tiles in involved (or referred to as the total number of times of row switching, as all storage units of the same tile are located at the same row of the memory) in the writing operation is 65. Further, the read data stored in Tile 0 to Tile 19 in FIG. 3 is as shown in FIG. 4b, wherein the 0^{th} to 3^{rd} sets read data is read from Tile 0, the 4^{th} to 7^{th} sets of read data is read from Tile 5, the 8^{th} to 11^{th} sets of read data is read from Tile 10, the 12^{th} set of read data is read from Tile 15, the 13^{th} to 16^{th} sets of read data is read from Tile 0, . . . , the 229^{th} to 232^{nd} sets of read data is read from Tile 14, and the 233^{rd} set of read data is read from Tile 19. Thus, the total number of times of changing the tiles involved (or referred to as the total number of times of row switching) in the reading operation is 72.

It is known from the above description and FIG. 4a and FIG. 4b that, Tile 4, Tile 9 and Tile 14 to Tile 19 contain storage spaces that are not utilized, which means such current tile technology results in an excessive waste in memory space. Further, the total number of times of row switching involved in the writing and reading operations is 137 times, which need to be further reduced in order to enhance the performance of the time de-interleaving process.

### SUMMARY OF THE INVENTION

The invention is directed to a time de-interleaving circuit and a time de-interleaving method to reduce the number of times of memory access and to enhance utilization efficiency of memory space of a time de-interleaving process.

The present invention discloses a de-interleaving circuit that performs a time de-interleaving process on a time interleaved block of an interleaved signal. The time interleaved block includes a plurality of information units. According to an embodiment, the de-interleaving circuit includes: an input buffer, buffering the information units; a writing address generator, generating a plurality of writing addresses according to a predetermined rule to write the information units buffered in the input buffer to a memory; a reading address generator, generating a plurality of reading addresses according to the predetermined rule to read the information units stored in the memory; and an output buffer, buffering the information units read from the memory. The information units are stored in a plurality of tiles when stored in the memory. Each of the tiles is a part or all of the storage units of one row of the memory. A memory address associated with each of the tiles is different from a memory address associated with any other tile. The tiles correspond to a plurality of regions of the time interleaved block according to the predetermined rule. The plurality of regions include a first region and a second region, and the dimensions of each tile in the first region are different from the dimensions of each tile in the second region.

The present invention further discloses a de-interleaving method applied to a signal receiving device to perform a time de-interleaving process on an interleaved signal. A time interleaved block of the interleaved signal includes a plurality of information units. According to an embodiment of the present invention, the de-interleaving method includes: generating a plurality of writing addresses according to a predetermined rule; generating a plurality of reading addresses according to the predetermined rule; and storing the information units to a memory according to the writing addresses, and outputting the information units from the memory according to the reading addresses. The information units are stored in a plurality of tiles when stored in the memory. Each of the tiles is a part or all of the storage units of one row of the memory. A memory address associated with each of the tiles is different from a memory address associated with any other tile. The tiles correspond to a plurality of regions of the time interleaved block according to the predetermined rule. The plurality of regions include a first region and a second region. In a same-row writing operation, a quantity of the information units allowed to be successively written to each tile in the first region is different from a quantity of the information units allowed to be successively written to each tile in the second region.

The above and other aspects of the invention will become better understood with regard to the following detailed description of the preferred but non-limiting embodiments. The following description is made with reference to the accompanying drawings.

### BRIEF DESCRIPTION OF THE DRAWINGS

FIG. 1 is a function block diagram of a conventional signal receiver;

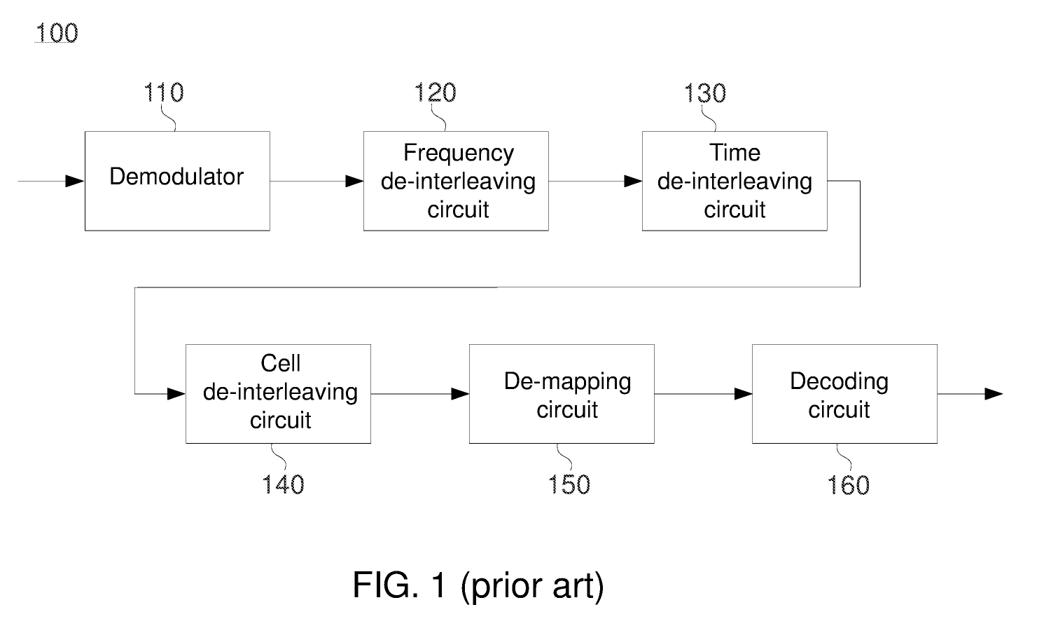

FIG. 2a is a schematic diagram of a data writing sequence of a time de-interleaving process;

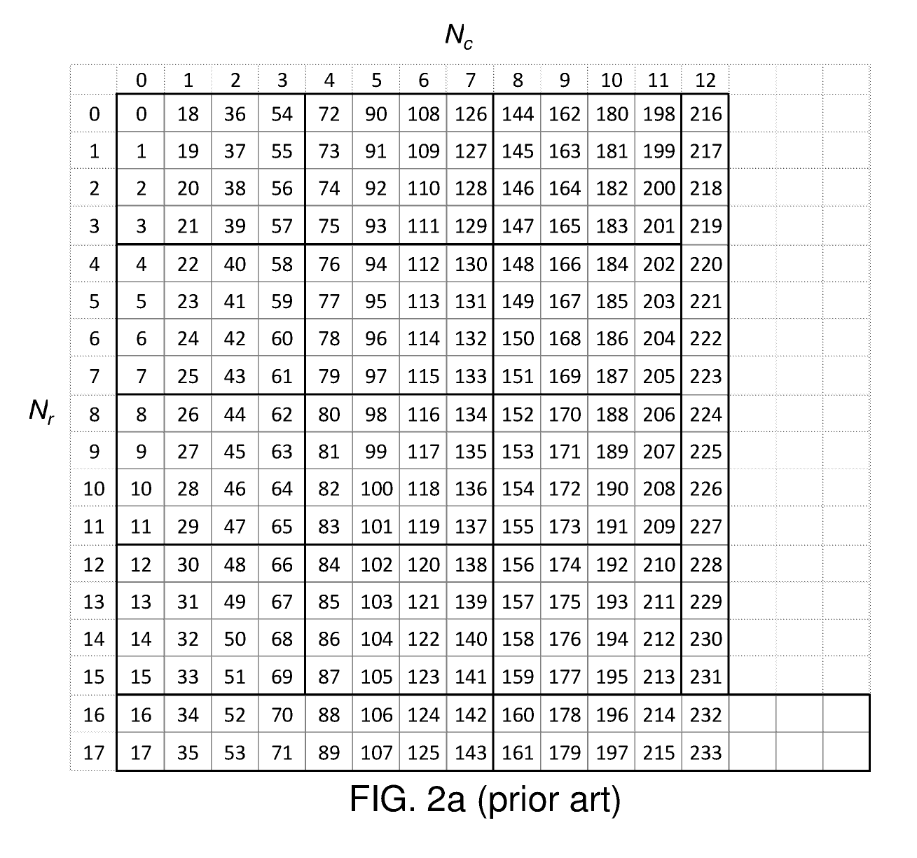

FIG. 2b is a schematic diagram of a data reading sequence of a time de-interleaving process;

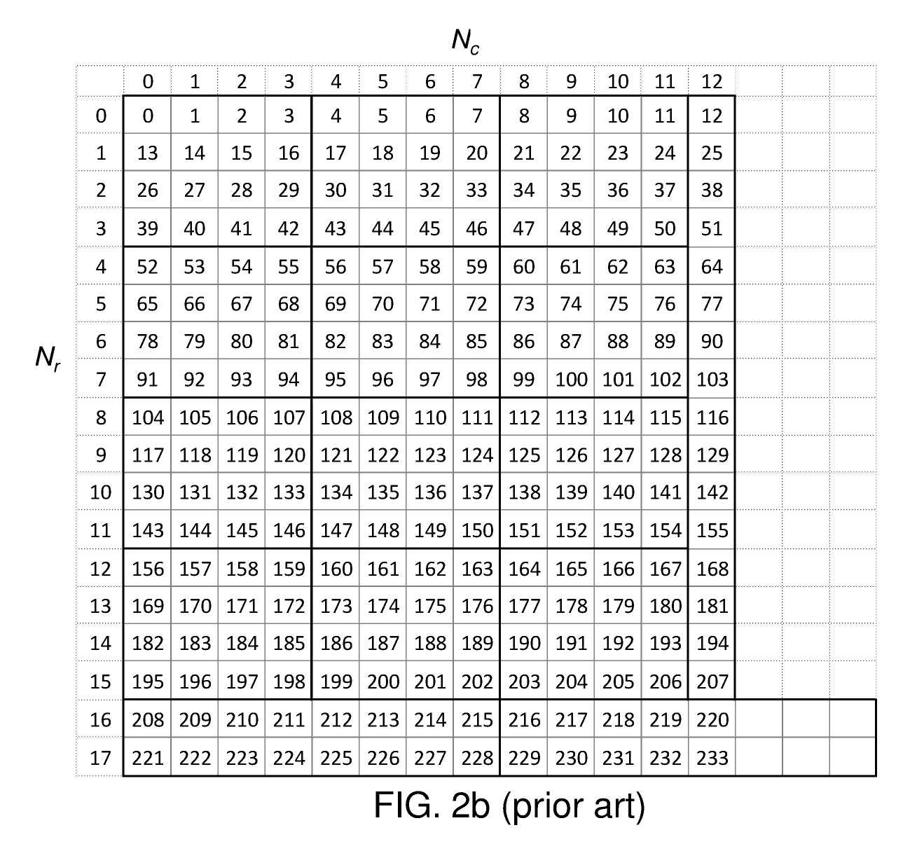

FIG. 3 is a schematic diagram of memory tiles needed for accessing data in FIG. 2a and FIG. 2b;

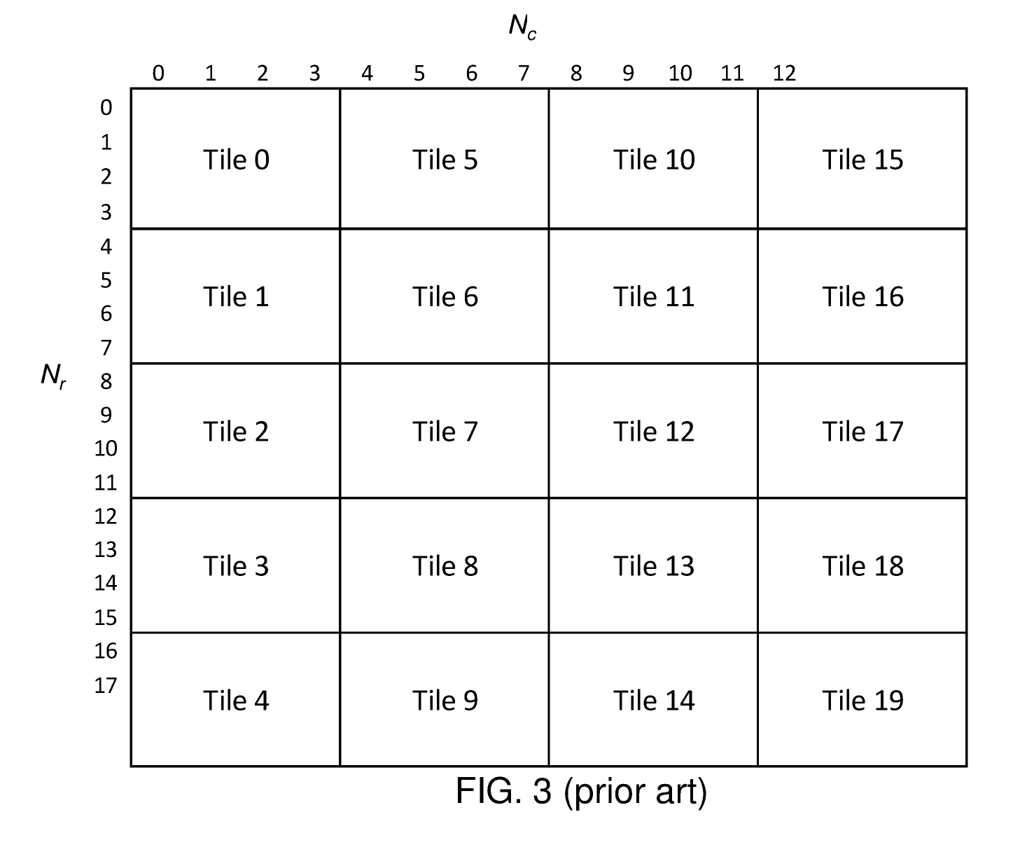

FIG. 4a is a schematic diagram of the memory tiles in FIG. 3 used in a writing operation according to a data writing sequence;

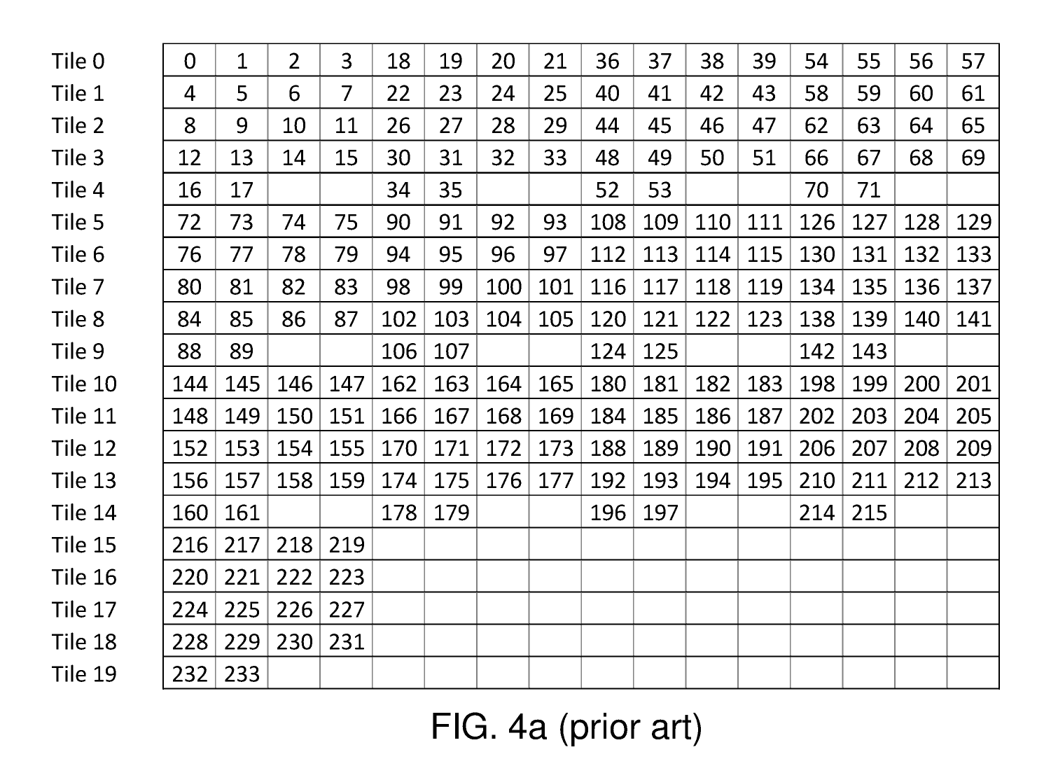

FIG. 4b is a schematic diagram of the memory tiles in FIG. 3 used in a reading operation according to a data reading sequence;

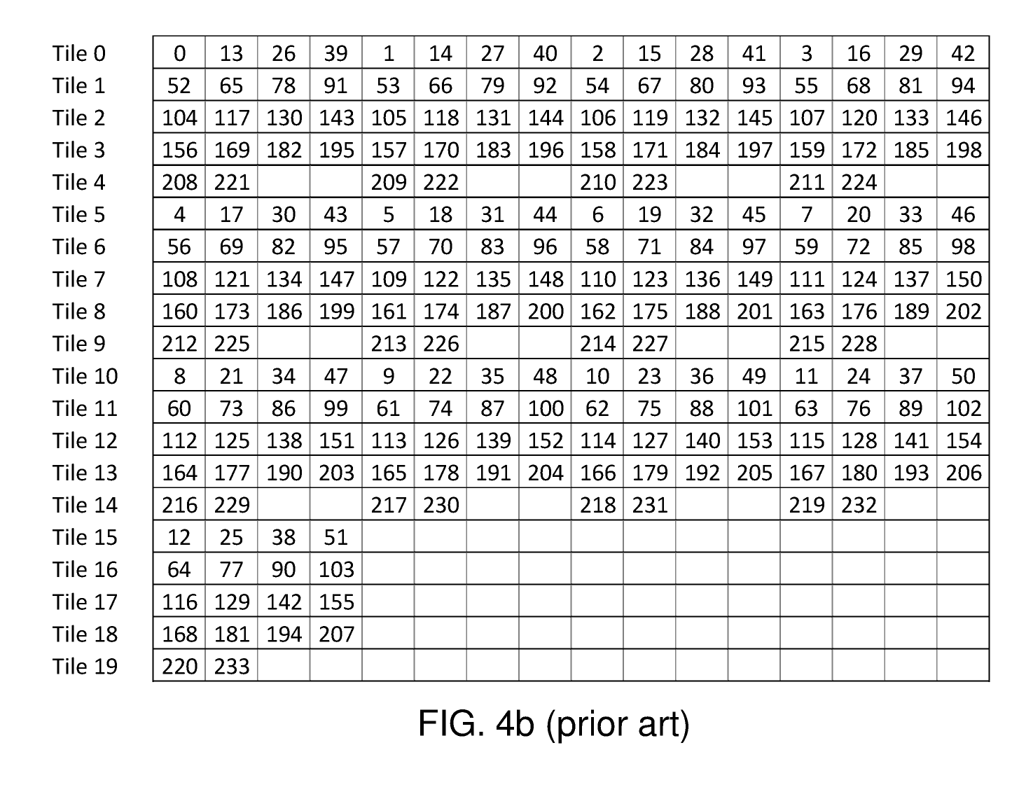

FIG. 5 is a block diagram of a time de-interleaving circuit according to an embodiment of the present invention;

FIG. 6a is a schematic diagram of a data writing sequence of a time de-interleaving process;

FIG. 6b is a schematic diagram of a data reading sequence of a time de-interleaving process;

FIG. 7 is a schematic diagram of memory tiles needed for accessing data in FIG. 6a and FIG. 6b;

FIG. 8a is a schematic diagram of the memory tiles in FIG. 7 used in a writing operation according to a data writing sequence;

FIG. 8b is a schematic diagram of the memory tiles in FIG. 7 used in a reading operation according to a data reading sequence;

FIG. 9a is a schematic diagram of a data writing sequence of a time de-interleaving process;

FIG. 9b is a schematic diagram of a data reading sequence of a time de-interleaving process;

FIG. 10 is a schematic diagram of memory tiles needed for accessing data in FIG. 9a and FIG. 9b;

FIG. 11a is a schematic diagram of the memory tiles in FIG. 10 used in a writing operation according to a data writing sequence;

FIG. 11b is a schematic diagram of the memory tiles in FIG. 10 used in a reading operation according to a data reading sequence; and

FIG. 12 is a flowchart of a time de-interleaving process according to an embodiment of the present invention.

### DETAILED DESCRIPTION OF THE INVENTION

The present invention discloses a time de-interleaving circuit and a time de-interleaving method, which are capable of effectively reducing the number of times that time de-interleaving process accesses a memory in a as well as the memory capacity needed for the time de-interleaving process to enhance both performance and cost-effectiveness.

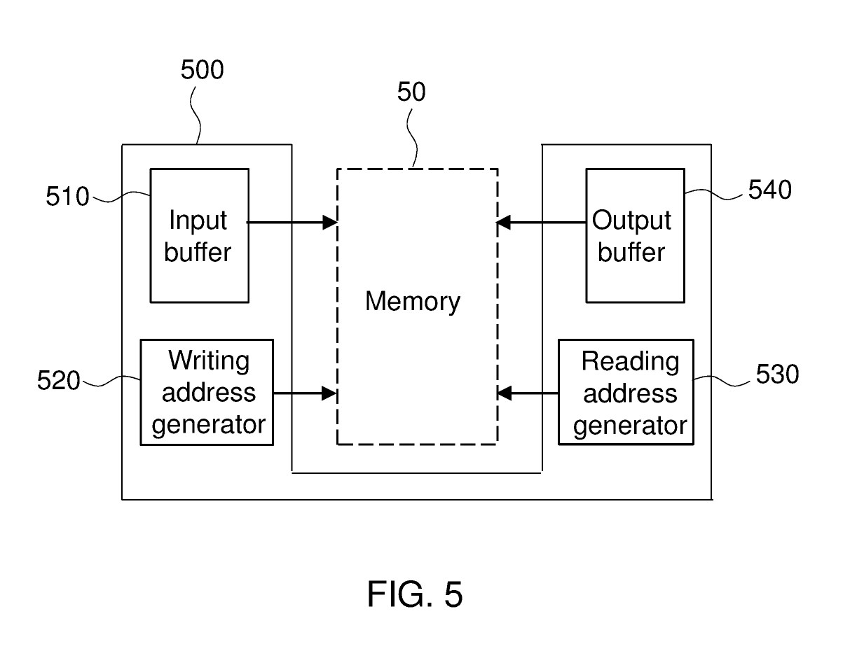

FIG. 5 shows a block diagram of a time de-interleaving circuit according to an embodiment of the present invention. A time de-interleaving circuit 500 in FIG. 5 is located at a signal receiver of a communication system to perform a time de-interleaving process on an interleaved signal. The interleaved signal includes a time interleaved (TI) block that includes a plurality of information units. The time de-interleaving circuit 500 includes an input buffer 510, a writing address generator 520, a reading address generator 530 and an output buffer 540. The input buffer 510 buffers the information units. The writing address generator 520 generates a plurality of writing addresses according to a predetermined rule to write the information units buffered in the input buffer 510 to a memory 50. The memory 50 may be included in the time de-interleaving circuit 500, or may be provided outside the time de-interleaving circuit 500. The reading address generator 530 generates a plurality of reading addresses according to the predetermined rule to read the information units from the memory 50. The output buffer 540 buffers the information units read from the memory 50.

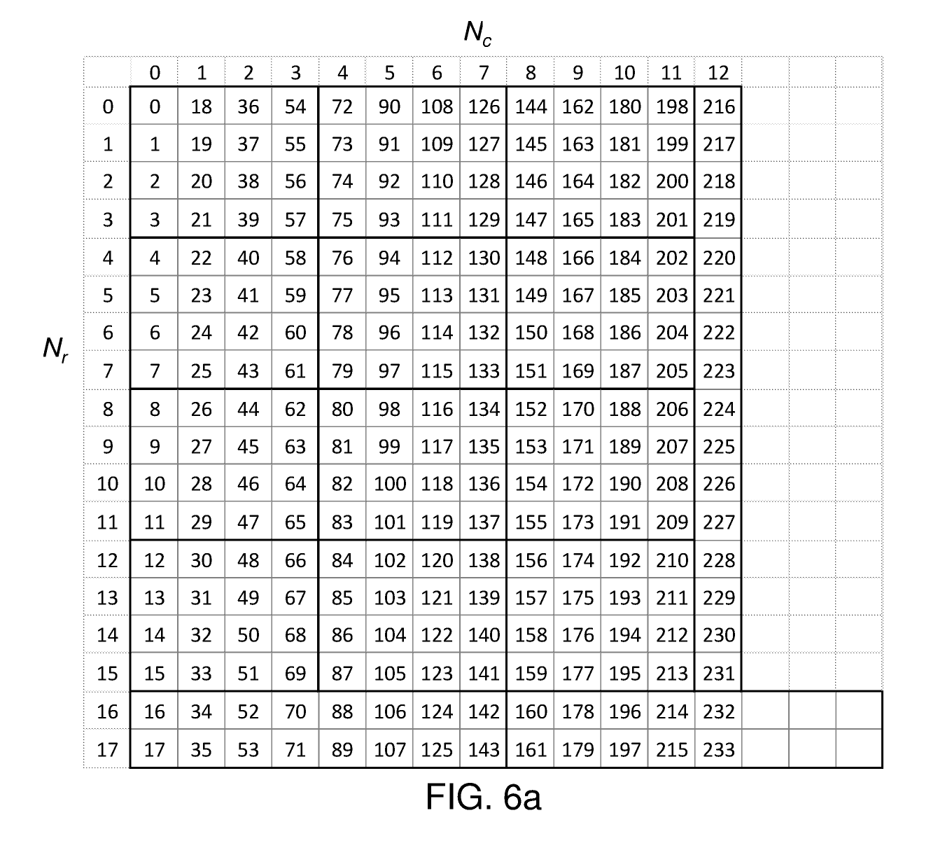

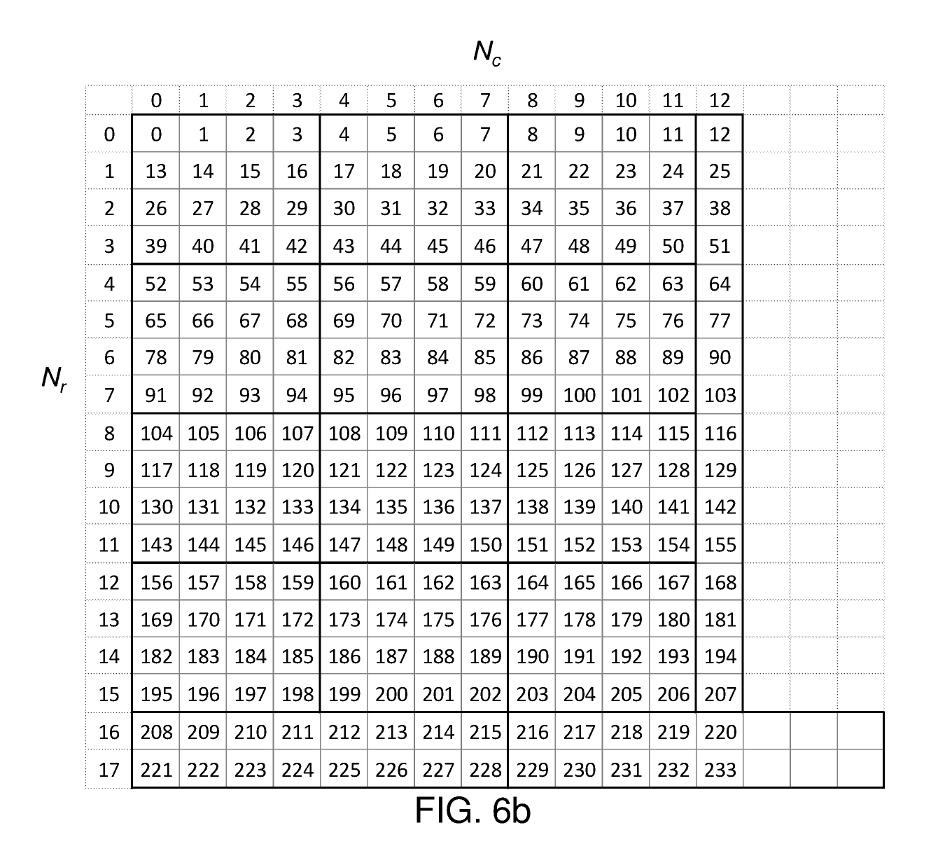

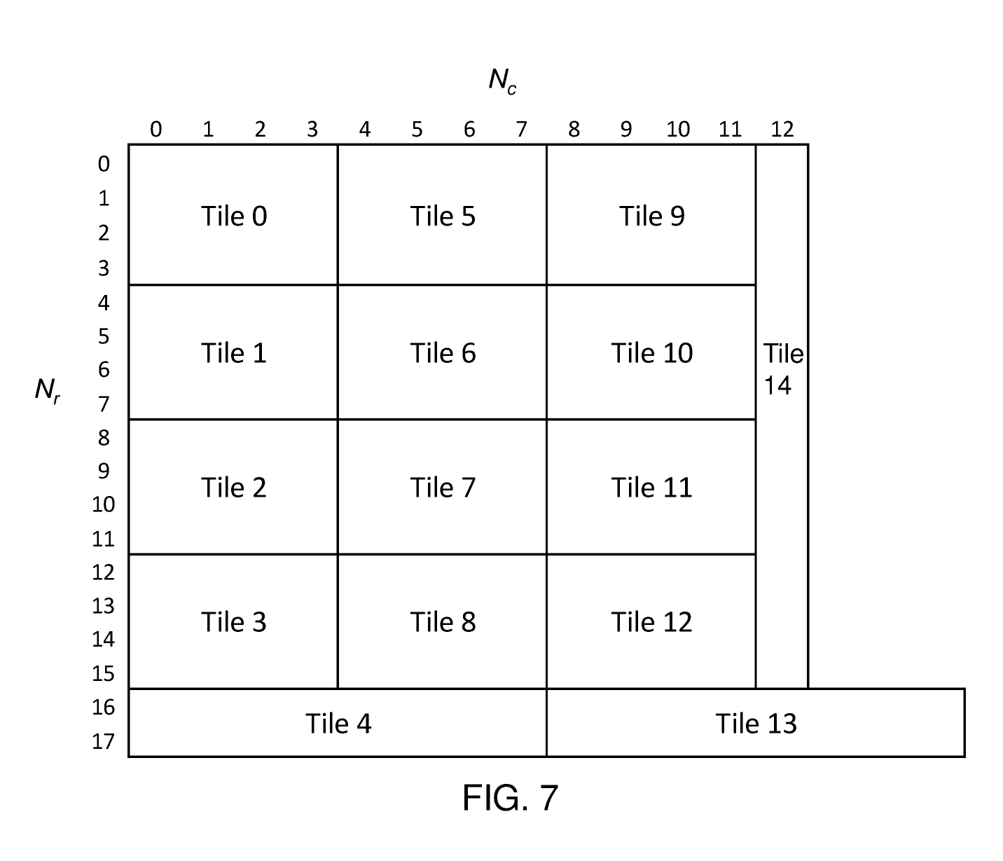

More specifically, the above information units are information units of Nᵣ rows multiplied by N_{c} columns, where Nᵣ and N_{c} define the memory size that the TI block needs. Further, Nᵣ is associated with a maximum quantity of consecutive information units under a vertical reading/writing sequence (the maximum quantity of consecutive information units associated with Nᵣ under a vertical reading/writing sequence is 18 in FIG. 6a), N_{c} is maximum quantity of consecutive information units under a horizontal reading/writing sequence (the maximum quantity of consecutive information units associated with N_{c} under a horizontal reading/writing sequence is 13 in FIG. 6a), and Nᵣ and N_{c} are both positive integers. The information units are divided into a plurality of parts, each of which stored in a tile. Each tile is a part or all of the storage units of one row of the memory 50. Thus, the access of the information units in the same tile does not involve any row switching access operation of the memory 50. Further, the memory address associated with each tile is different from the memory address associated with any other tile. These tiles belong to a plurality of regions according to the foregoing predetermined rule, and the dimensions of each tile in each region are different from the dimensions of any other tile in any other region. The dimensions of the tiles may be understood as a size formed by Tᵣ multiplied by T_{c} information units, where Tᵣ is associated with the maximum quantity of information units allowed to be successively written in a vertical access operation when the same tile is accessed (e.g., when the same tile is written). For example, in FIG. 7, the maximum quantity of information units allowed to be successively written in a vertical access operation associated with Tᵣ of Tile 0 is 4, the maximum quantity of information units allowed to be successively written in a vertical access operation associated with Tᵣ of Tile 4 is 2, and the maximum quantity of information units allowed to be successively written in a vertical access operation associated with Tᵣ of Tile 14 is 16. Further, T_{c} is associated with the maximum quantity of information units allowed to be successively read in a horizontal access operation when the same tile is accessed (e.g., when the same tile is read). For example, in FIG. 7, the maximum quantity of information units allowed to be successively read in a horizontal access operation associated with T_{c} of Tile 0 is 4, the maximum quantity of information units allowed to be successively read in a horizontal access operation associated with T_{c} of Tile 4 is 8, and the maximum quantity of information units allowed to be successively read in a horizontal access operation associated with T_{c} of Tile 14 is 1. Therefore, in a same-row access operation (e.g., when information units in the same tile are accessed), the quantities of information units allowed to be successively written to and/or read from two differently-dimensioned tiles are different. For example, the two differently-dimensioned tiles are one tile having dimensions Tᵣ₁×T_{c1} and one other tile having dimensions Tᵣ₂×T_{c2}, where Tᵣ₁×T_{c1} may be equal to Tᵣ₂×T_{c2}, but Tᵣ₁ is not equal to Tᵣ₂ and/or T_{c1} is not equal to T_{c2}. It should be noted that, to simplify the access operation, the quantity of storage units corresponding to each tile is equal to the quantity of storage units corresponding to any other tile. In other words, the storage capacities corresponding to individual tiles are equal. The above example is not to be construed as a limitation to the present invention. Further, the terms “vertical” and “horizontal” are used for easy understanding, and are not to be interpreted as actual spatial directions.

In continuation, for example, the foregoing information units of Nᵣ rows multiplied by N_{c} columns are information units of 18 rows multiplied by 13 columns (i.e., Nᵣ=18, and N_{c}=13). FIG. 6a and FIG. 6b show schematic diagrams of writing and reading sequences of these information units, which are stored in a plurality of tiles, as shown in FIG. 7. In FIG. 7, according to the predetermined rule, Tile 0 to Tile 14 belong to three regions—the region 0, the region 1 and the region 3. The region 0 is formed by the 0^{th} to 15^{th} rows among the 18 rows and the 0^{th} to 11^{th} columns among the 13 columns. Each tile is a basic tile having dimensions of 4 rows multiplied by 4 columns, and each storage unit of each basic tile stores at least one information unit. The region 1 includes the 0^{th} to 15^{th} rows among the 18 rows and the 12^{th} column among the 13 columns, and each of the tiles has dimensions of 16 rows multiplied by 1 column. Because the number of columns is less than 4, the tile in the region 1 cannot form the basic tile. The region 2 includes the 16^{th} and 17^{th} rows among of the 18 rows and the 0^{th} to 12^{th} columns among the 13 columns, and each tile has dimensions of 2 rows multiplied by 8 columns. Because the number of rows is less than 4, the tile in the region 2 cannot form the basic tile either.

More specifically, based on the number of rows (Nᵣ=18) and the number of columns (N_{c}=13) of the information units and the dimensions Tᵣ×T_{c} (4×4 in this example) of the basic tile, an equation below may be applied to the foregoing predetermined rule to determine the number of tiles in the region 0:

Maximum number N_{c}_{_}₀ of successive horizontal tiles: └N_{c}/T_{c}┘=└13/4┘=3
Maximum number Nᵣ_{_}₀ of successive vertical tiles: └Nᵣ/Tᵣ┘=└18/4┘=4

Quantity of tiles in region 0: N_{c}_{_}₀×Nᵣ_{_}₀=12

In the above, └ ┘ means rounding down to an integer function. Further, by causing the dimensions of the tiles in the region 1 to be equal to Tᵣ¹×T_{c}¹, an equation below may be applied to the foregoing predetermined rule to determine the quantity of the tiles in the region 1:

T_{c}¹=2^{┌log}^{₂}^{(N}^{_{c}}^{-└N}^{_{c}}^{/T}^{_{c}}^{┘×T}^{_{c}}^{)┐}=1

Tᵣ¹=Tᵣ×T_{c}/T_{c}¹=16

Quantity of tiles in region 1: ┌([N_{c}/T_{c}]×T_{c})/T_{c}¹┐=┌16/16┐=1

In the above, ┌ ┐ represents rounding up to an integer function. Further, the dimensions of tiles in the region 2 are caused to be Tᵣ²×T_{c}², and an equation below may be applied to the foregoing predetermined rule to determine the quantity of the tiles in the region 2:

Tᵣ²=2=2^{┌log}^{₂}^{(N}^{ᵣ}^{-└N}^{ᵣ}^{/T}^{ᵣ}^{┘×T}^{ᵣ}^{)┐}=2

T_{c}²=Tᵣ×T_{c}/Tᵣ²=8

Quantity of tiles in region 2 ┌N_{c}/T_{c}²┐=┌13/8┐=2:

Therefore, the total quantity of tiles in the three regions is:

└N_{c}/T_{c}┘×└Nᵣ/Tᵣ┘+┌(└N_{c}/T_{c}┘×T_{c})/T_{c}¹┐+┌N_{c}/T_{c}²┐=+1+2=15

It should be noted that, the quantity of storage units in each tile in the embodiment is a power of 2, and the dimensions of the basic tile are not limited to the example in the application and may be determined by a designer based actual implementation requirements.

Refer to FIG. 6a, FIG. 6b and FIG. 7. As previously stated, FIG. 6a shows a vertical writing sequence of the information units. The numbers in the grids represent the writing orders of the information units, and a mapping relationship between the information units associated with these orders and the tiles may be learned from the position relationship in FIG. 6a and FIG. 7. For example, the information units in a block formed by the 0^{th} to 3^{rd} rows and 0^{th} to 3^{rd} columns in FIG. 6a map to Tile 0 in FIG. 7, and so forth. FIG. 6b shows a horizontal reading sequence of the information units. The numbers in the grids represent the reading orders, and the mapping relationship between the information units associated with these orders and the tiles may be learned from the position relationship in FIG. 6b and FIG. 7. For example, the information units in a block formed by the 0^{th} to 3^{rd} rows and 0^{th} to 3^{rd} columns in FIG. 6b map to Tile 0 in FIG. 7, and so forth. It should be noted that, the information units associated with two grids at corresponding positions in FIG. 6a and FIG. 6b (e.g., two grids formed at the intersection of the 1^{st} row and the 1^{st} column in FIG. 6a and FIG. 6b) are the same.

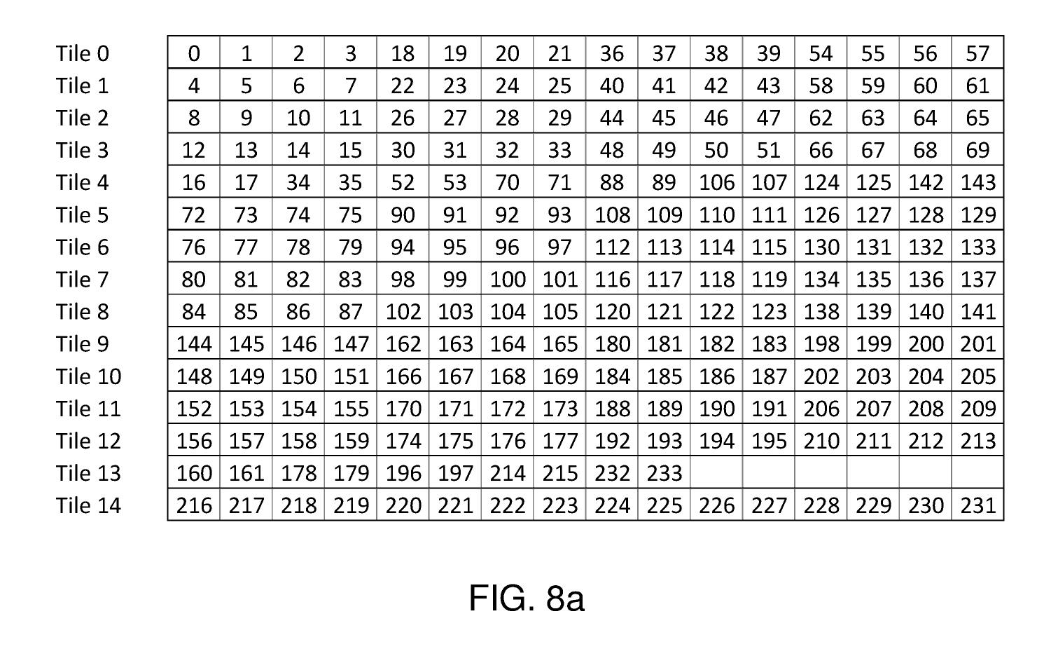

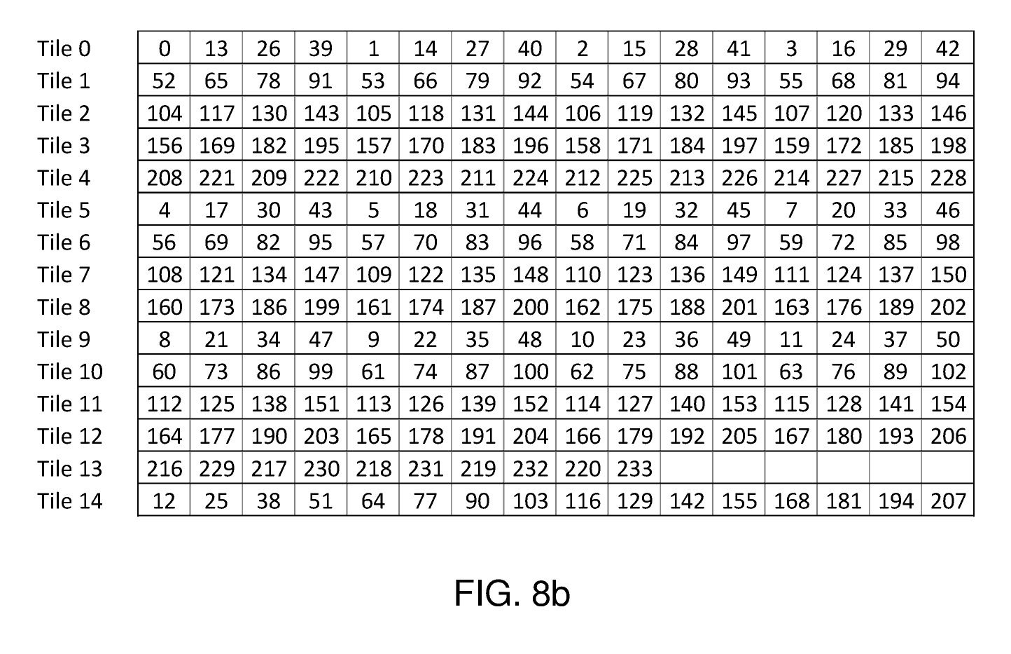

As previously stated, each tile is a part or all of the storage units of one row of the memory, and the access of the information units in the same tile does not involve any row switching access operation of the memory. Thus, by representing the tiles in FIG. 7 by the storage units in the same memory row, FIG. 6a and FIG. 6b may be respectively represented as FIG. 8a and FIG. 8b.

As shown in FIG. 8a, according to the writing sequence, the information units are written to the tiles as follows:
the 0^{th} to 3^{rd} information units are written to Tile 0;
the 4^{th} to 7^{th} information units are written to Tile 1;
the 8^{th} to 11^{th} information units are written to Tile 2;
the 12^{th} to 15^{th} information units are written to Tile 3;
the 16^{th} and 17^{th} information units are written to Tile 4;
the 18^{th} to 21^{st} information units are written to Tile 0;
. . .
the 34^{th} to 35^{th} information units are written to Tile 4;
. . .
the 72^{nd} to 75^{th} information units are written to Tile 5;
the 76^{th} to 79^{th} information units are written to Tile 6;
the 80^{th} to 83^{rd} information units are written to Tile 7;
the 84^{th} to 87^{th} information units are written to Tile 8;
the 88^{th} and 89^{th} information units are written to Tile 4;
. . .
the 216^{th} to 231^{st} information units are written to Tile 14; and
the 232^{nd} and 233^{rd} information units are written to Tile 13.

Thus, the total number of times of tile changing (or the number of times of row switching, as all of the storage units of the same tile are located at the same row of the memory) involved in the above writing operation 62 times.

As shown in FIG. 8b, according to the reading sequence, the information units are read from the tiles as follows:
the 0^{th} to 3^{rd} information units are read from Tile 0;
the 4^{th} to 7^{th} information units are read from Tile 5;
the 8^{th} to 11^{th} information units are read from Tile 9;
the 12^{th} information unit is read from Tile 14;
the 13^{th} to 16^{th} information units are read from Tile 0;
. . .
the 208^{th} to 215^{th} information units are read from Tile 4;
the 216^{th} to 220^{th} information units are read from Tile 13;
the 221^{st} to 228^{th} information units are read from Tile 4; and
the 229^{th} to 233^{rd} information units are read from Tile 13.

Thus, the total number of times of tile changing (or the number of row switching) is 68 times.

It is known from FIG. 8a and FIG. 8b and the foregoing description that, the total number of times of tile changing (or the number of row switching) involved in the de-interleaving process of the embodiment is 62+68=130 times, and there is only one tile (i.e., Tile 13) that has storage space not stored with information units. Therefore, compared to the prior art, the access efficiency and storage space utilization rate of the embodiment are higher.

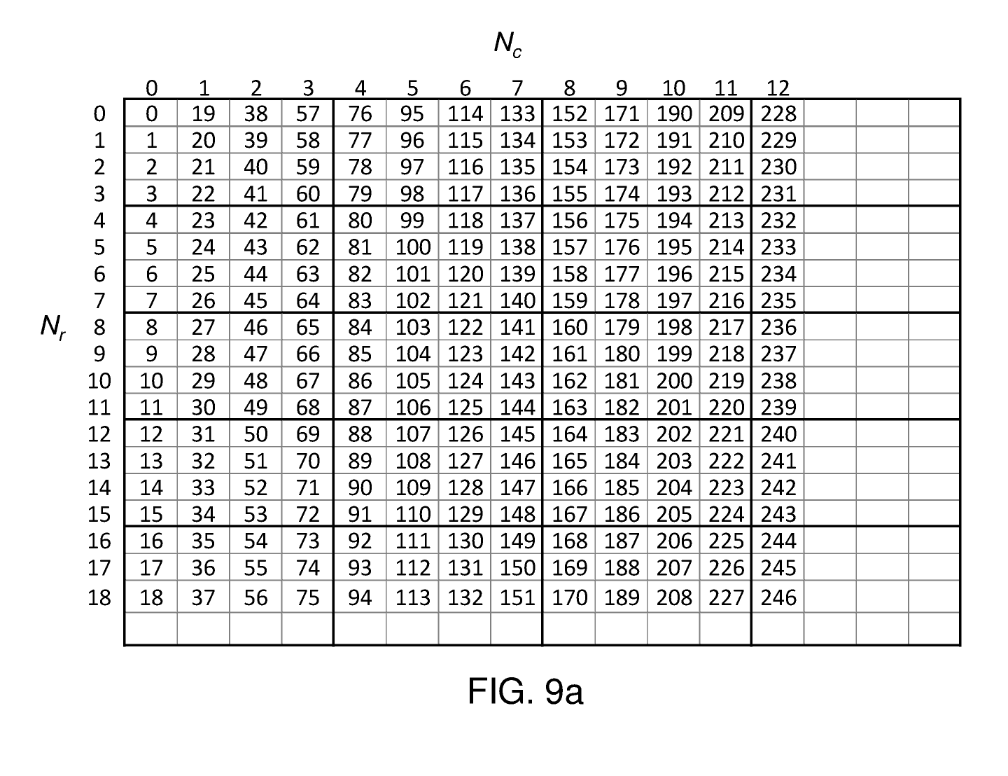

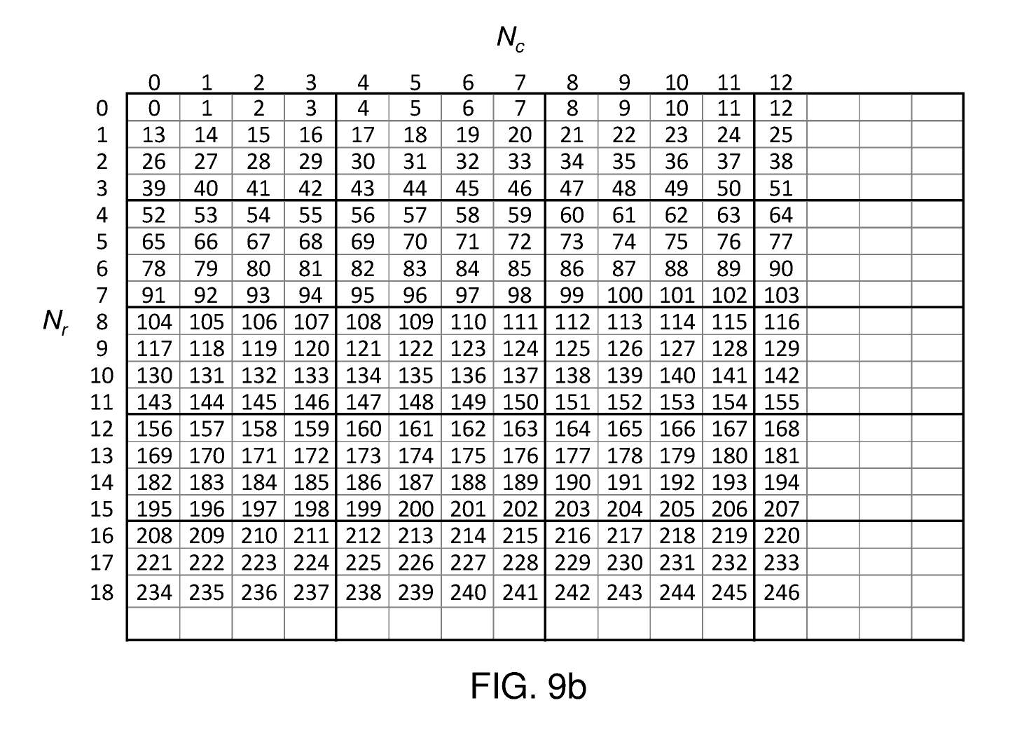

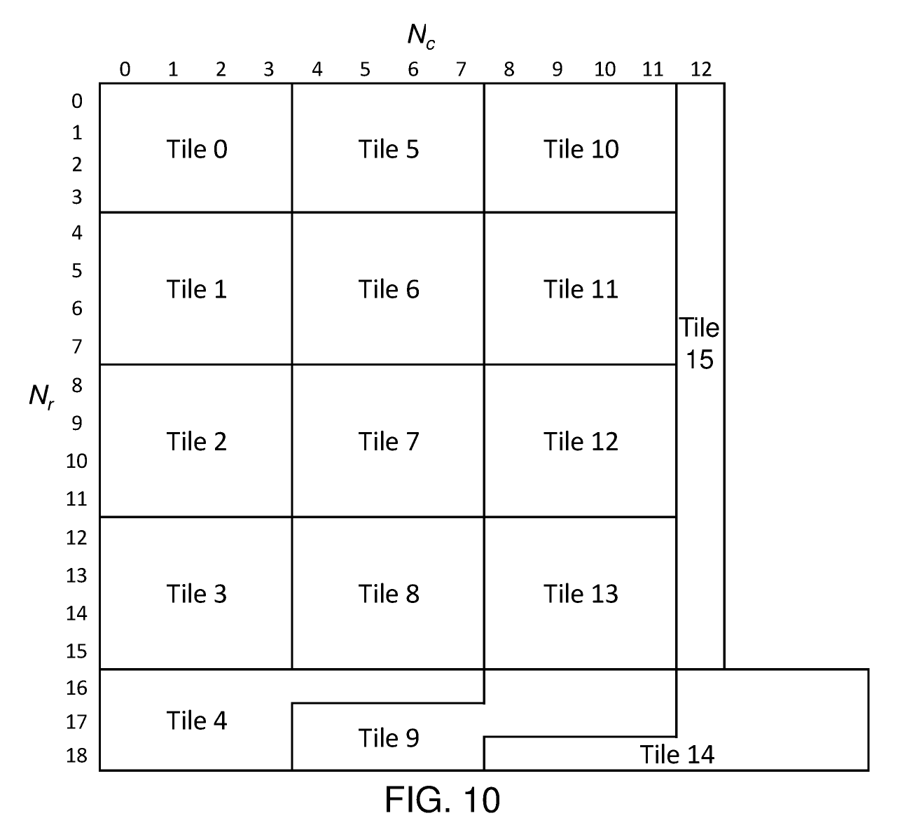

It should be noted that, one person skilled in the art may modify the predetermined rule for determining the tile region based on the disclosure of the application, so as to apply the modified predetermined rule to time de-interleaving. For example, the information units received by the time de-interleaving circuit 500 are information units of 19 rows multiplied by 13 columns (i.e., Nᵣ=19, and N_{c}=13), and the FIG. 9a and FIG. 9b respectively show schematic diagrams of writing and reading sequences of the information units. FIG. 10 shows a schematic diagram of these information units stored in a plurality of tiles. In FIG. 10, according to the modified predetermined rule, Tile 0 to Tile 15 belong to three regions—a region 0, a region 1 and a region 2. The region 0 is formed by 0^{th} to 15^{th} rows among the 19 rows and the 0^{th} to 11^{th} columns among the 13 columns. Each of the tiles in the region 0 is a basic tile having dimensions of 4 rows multiplied by 4 columns, and each storage unit of each basic tile stores at least one information unit. The region 1 includes 0^{th} to 15^{th} rows among the 19 rows and the 12^{th} column among the 13 columns. Each of the tiles in the region 1 has dimensions of 16 rows multiplied by 1 column, and cannot form the basic tile because there are less than 4 columns. The region 2 includes 16^{th} to 18^{th} rows among the 19 rows and the 0^{th} to 12^{th} columns among the 13 columns. Each of the tiles in the region 2 includes 16 storage units. However, the dimensions of different tiles may not be equal, and the dimensions of each tile may not be dimensions of a rectangle. Further, the maximum number of rows is smaller than 4, and so each tile in the region 2 cannot form the basic tile.

More specifically, according to the number of rows (Nᵣ=19) and the number of columns (N_{c}=13) of the information units and the dimensions Tᵣ×T_{c} (4×4 in this example) of the basic tile, an equation below may be applied to the modified predetermined rule to determine the quantity of tiles in the region 0:

Maximum number N_{c}_{_}₀ of successive horizontal tiles: └N_{c}/T_{c}┘=└13/4┘=3
Maximum number Nᵣ_{_}₀ of successive vertical tiles: └Nᵣ/Tᵣ┘=└19/4┘=4
Quantity of tiles in region 0: N_{c}_{_}₀×Nᵣ_{_}₀=12

Further, an equation below may be applied to the modified predetermined rule to determine the quantity of tiles in the region 1:

┌(└Nᵣ/Tᵣ┘×Tᵣ)×(N_{c}−└N_{c}/T_{c}┘×T_{c})/(Tᵣ×T_{c})┐=[(4×4)×(13−3×4)/16┐=└16/16┐=1

Further, an equation below may be applied to the modified predetermined rule to determine the quantity of tiles in the region 2:

└(Nᵣ−┌Nᵣ/Tᵣ┐×Tᵣ)×N_{c}/(Tᵣ×T_{c})┐=┌(19−4×4)×13/16┐=┌39/16┐=3

Thus, the sum of the quantities of tiles in the three regions is:

└Nᵣ/Tᵣ┘×└N_{c}/T_{c}┘+┌(└N_{c}/T_{c}┘×T_{c})×(Nᵣ−└Nᵣ/Tᵣ┘×Tᵣ)/(Tᵣ×T_{c})┐+┌(N_{c}−└N_{c}/T_{c}┘×T_{c})×Nᵣ/(Tᵣ×T_{c})┐=12+1+3=16

It should be noted that, the quantity of storage units in each tile in the embodiment is a power of 2, and the dimensions of the basic tile are not limited to the example in the application and may be determined by a designer based actual implementation requirements.

Refer to FIG. 9a, FIG. 9b and FIG. 10. As previously stated, FIG. 9a shows a vertical writing sequence of the information units. The numbers in the grids formed at the intersections of the rows and columns represent the writing orders of the information units, and a mapping relationship between the information units associated with these orders and the tiles may be learned from the position relationship in FIG. 9a and FIG. 10. FIG. 9b shows a horizontal reading sequence of the information units. The numbers in the grids represent the reading orders, and the mapping relationship between the information units associated with these orders and the tiles may be learned from the position relationship in FIG. 9b and FIG. 10. It should be noted that, the information units associated with two grids at corresponding positions in FIG. 9a and FIG. 9b are the same.

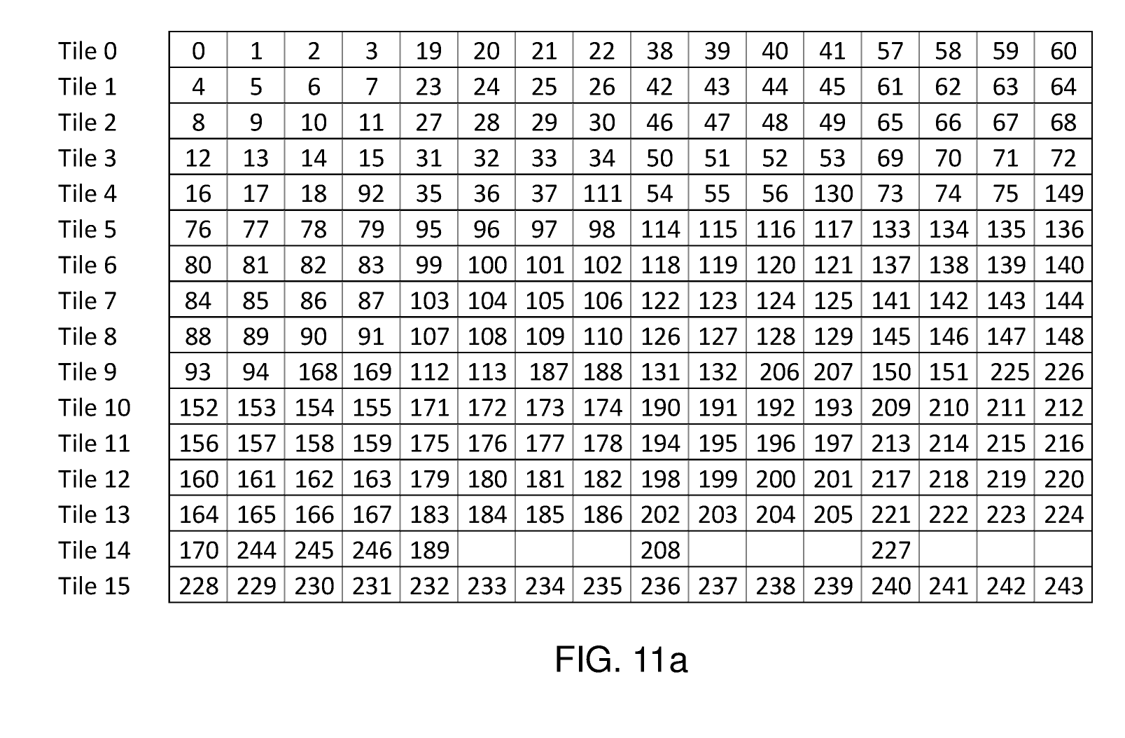

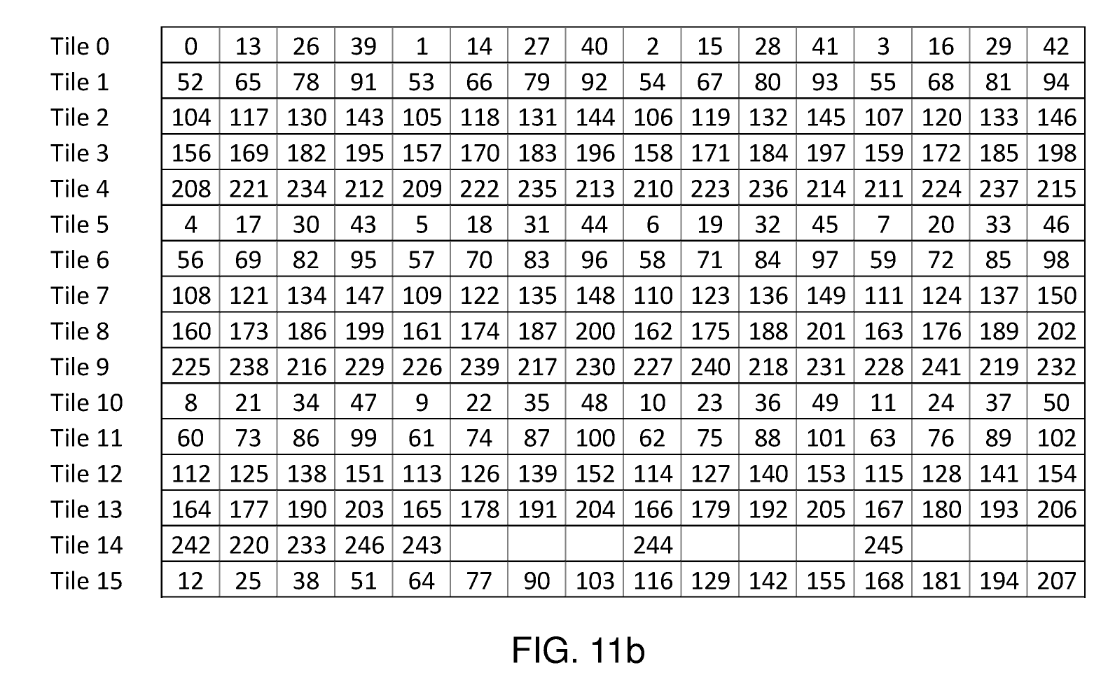

As previously stated, each tile is a part or all of the storage units of one row of the memory, and the access of the information units in the same tile does not involve any row switching access operation of the memory. Thus, by representing the tiles in FIG. 10 by the storage units in the same memory row, FIG. 9a and FIG. 9b may be respectively represented as FIG. 11a and FIG. 11b.

As shown in FIG. 11a, according to the writing sequence, the information units are written to the tiles as follows:
the 0^{th} to 3^{rd} information units are written to Tile 0;
the 4^{th} to 7^{th} information units are written to Tile 1;
the 8^{th} to 11^{th} information units are written to Tile 2;
the 12^{th} to 15^{th} information units are written to Tile 3;
the 16^{th} to 18^{th} information units are written to Tile 4;
. . .
the 76^{th} to 79^{th} information units are written to Tile 5;
the 80^{th} to 83^{rd} information units are written to Tile 6;
the 84^{th} to 87^{th} information units are written to Tile 7;
the 88^{th} to 91^{st} information units are written to Tile 8;
the 92^{nd} information unit is written to Tile 4;
the 93^{rd} to 94^{th} information units are written to Tile 9;
. . .
the 209^{th} to 212^{th} information units are written to Tile 10;
the 213^{th} to 216^{th} information units are written to Tile 11;
the 217^{th} to 220^{th} information units are written to Tile 12;
the 221^{st} to 224^{th} information units are written to Tile 13;
the 225^{th} and 226^{th} information units are written to Tile 9;
the 227^{th} information unit is written to Tile 14;
. . .
the 228^{th} to 243^{rd} information units are written to Tile 15; and
the 244^{th} to 246^{th} information units are written to Tile 14.

Thus, the total number of times of tile changing (or the number of times of row switching) involved in the above writing operation 70 times.

As shown in FIG. 11b, according to the reading sequence, the information units are read from the tiles as follows:
the 0^{th} to 3^{rd} information units are read from Tile 0;
the 4^{th} to 7^{th} information units are read from Tile 5;
the 8^{th} to 11^{th} information units are read from Tile 10;
the 12^{th} information unit is read from Tile 15;
the 13^{th} to 16^{th} information units are read from Tile 0;
. . .
the 208^{th} to 215^{th} information units are read from Tile 4;
the 216^{th} to 219^{th} information units are read from Tile 9;
the 220^{th} information unit is read from Tile 14;
the 221^{st} to 224^{th} information units are read from Tile 4;
the 225^{th} to 232^{nd} information units are read from Tile 9;
the 233^{rd} information unit is read from Tile 14;
the 234^{th} to 237^{th} information units are read from Tile 4;
the 238^{th} to 241^{st} information units are read from Tile 9; and
the 242^{nd} to 246^{th} information units are read from Tile 14.

Thus, the total number of times of tile changing (or the number of row switching) is 73 times.

It is known from FIG. 11a and FIG. 11b and the foregoing description that, the total number of times of tile changing (or the number of row switching) involved in the de-interleaving process of the embodiment is 70+73=143 times, and there is only one tile (i.e., Tile 14) that has storage space not stored with information units. Therefore, compared to the prior art, the access efficiency and storage space utilization rate of the embodiment are higher.

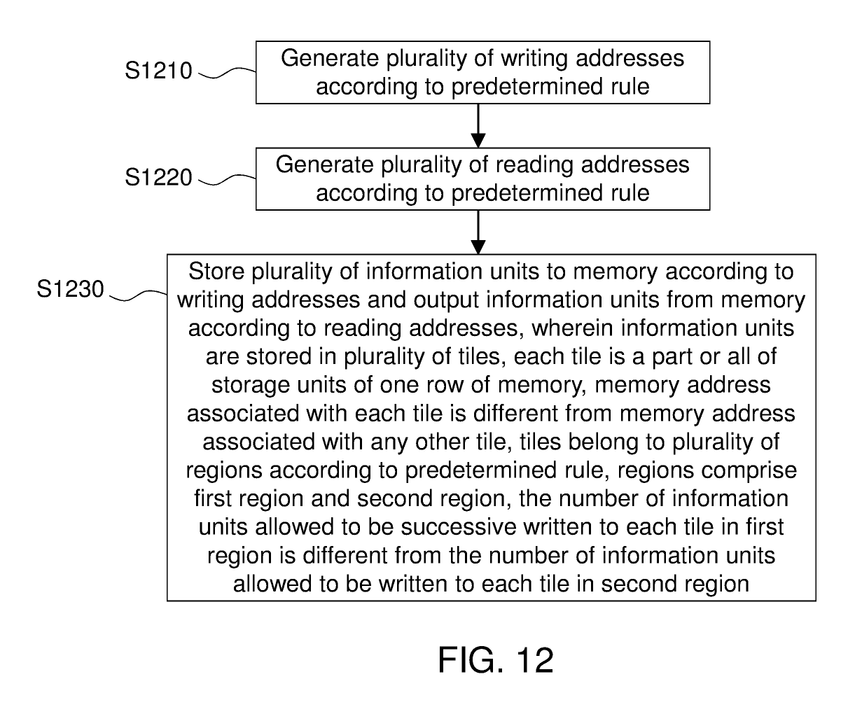

In addition to the foregoing circuit, the present invention further discloses a time de-interleaving method applied to a signal receiver of a communication system to perform a time de-interleaving process on a time interleaved block of an interleaved signal. The time interleaved block includes a plurality of information units. Referring to FIG. 12, the time de-interleaving method according to an embodiment of the present invention includes following steps.

In step S1210, a plurality of writing addresses are generated according to a predetermined rule.

In step S1220, a plurality of reading addresses are generated according to the predetermined rule.

In step S1230, the information units are stored to a memory according to the writing addresses, and are outputted from the memory according to the reading addresses. The information units are stored in a plurality of tiles, each of which being a part or all of the storage units of one row of the memory. A memory address associated with each tile is different from a memory address associated with any other tile. The tiles belong to a plurality of regions according to the predetermined rule. The regions include a first region and a second region. In one same-row writing operation, the quantity of information units allowed to be successively written to each tile of the first region is different from the quantity of information units allowed to be successively written to each tile in the second region.

One person skilled in the art may understand the implementation details and variations of the method of the present invention based on the disclosure of the foregoing circuit; that is, the technical features of the foregoing circuit may be reasonably applied to the method of the present invention. Without affecting the disclosure and possible implementation of the present invention, such repeated details are omitted herein.

It should be noted that, the time de-interleaving circuit may directly serve as a time interleaving circuit, and the time de-interleaving method may also directly serve as a time interleaving method.

In conclusion, the time de-interleaving circuit and the time de-interleaving method of the present invention are capable of reducing the number of times of accessing a memory as well as the memory capacity needed for the time de-interleaving process to enhance both performance and cost-effectiveness.

While the invention has been described by way of example and in terms of the preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A de-interleaving circuit, performing a time de-interleaving process on a time interleaved block of an interleaved signal, the time interleaved block comprising a plurality of information units, the de-interleaving circuit comprising:
an input buffer, buffering the information units;
a writing address generator, generating a plurality of writing addresses according to a predetermined rule to write the information units buffered in the input buffer to a memory;
a reading address generator, generating a plurality of reading addresses according to the predetermined rule to read the information units stored in the memory; and
an output buffer, buffering the information units read from the memory;
wherein, the information units are stored in a plurality of tiles, each of the tiles is a part or all of storage units of one row of the memory, a memory address associated with each of the tiles is different from a memory address associated with any other tile, the tiles correspond to a plurality of regions of the time interleaved block according to the predetermined rule, the regions comprise a first region and a second region, and dimensions of each of the tiles in the first region are different from dimensions of each of the tiles in the second region.

2. The de-interleaving circuit according to claim 1, wherein the time interleaved block comprises Nᵣ×N_{c} information units, where Nᵣ and N_{c} are positive integers, the regions comprise the first region, the second region and a third region, and dimensions of each of the tiles in the first region are different from dimensions of each of the tiles in the third region.

3. The de-interleaving circuit according to claim 1, wherein in a same-row writing operation, quantities of information units allowed to be successively written to any two differently-dimensioned tiles are different.

4. The de-interleaving circuit according to claim 1, wherein in a same-row reading operation, quantities of information units allowed to be successively read from any two differently-dimensioned tiles are different.

5. The de-interleaving circuit according to claim 1, wherein a quantity of storage units in each of the tiles is equal to a quantity of storage units in any other tile.

6. The de-interleaving circuit according to claim 1, wherein a quantity of storage units of each of the tiles is a power of 2.

7. The de-interleaving circuit according to claim 1, wherein each of the storage units of each of the tiles in the first region stores at least one of the information units.

8. The de-interleaving circuit according to claim 1, wherein at least one storage unit of at least one of the tiles in the second region does not store any of the information units.

9. The de-interleaving circuit according to claim 1, wherein a quantity of all of the tiles in the first region is greater than a quantity of all of the tiles in the second region.

10. The de-interleaving circuit according to claim 9, wherein the regions comprise the first region, the second region and a third region, dimensions of each of the tiles in the first region are different from dimensions of each of the tiles in the third region, and the quantity of all of the tiles in the first region is greater than the quantity of all of the tiles in the third region.

11. The de-interleaving circuit according to claim 1, wherein each of the tiles in the first region is Tᵣ×T_{c} storage units, each of the tiles in the second region is Tᵣ₁×T_{c1} storage units, a value of Tᵣ determines a quantity of information units allowed to be successively written to each of the tiles in the first region in a same-row writing operation, a value of T_{c} determines a quantity of information units allowed to be successively read from each of the tiles in the first region in a same-row reading operation, a value of Tᵣ₁ determines a quantity of information units allowed to be successively written to each of the tiles in the second region in a same-row writing operation, a value of T_{c1} determines a quantity of information units allowed to be successively read from each of the tiles in the second region in a same-row reading operation, Tᵣ₁ is not equal to Tᵣ, T_{c1} is not equal to T_{c}, Tᵣ multiplied by T_{c} is equal to Tᵣ₁ multiplied by T_{c1}, and Tᵣ, Tᵣ₁, T_{c} and T_{c1} are positive integers.

12. The de-interleaving circuit according to claim 11, wherein the regions comprise the first region, the second region and a third region, each of the tiles in the third region is Tᵣ₂×T_{c2} storage units, a value of Tᵣ₂ determines a quantity of information units allowed to be successively written to each of the tiles in the third region in a same-row writing operation, a value of T_{c2} determines a quantity of information units allowed to be successively read from each of the tiles in the third region in a same-row reading operation, Tᵣ₂ is not equal to Tᵣ, T_{c2} is not equal to T_{c}, Tᵣ multiplied by T_{c} is equal to Tᵣ₂ multiplied by T_{c2}, and Tᵣ₂ and T_{c2} are positive integers.

13. The de-interleaving circuit according to claim 12, wherein Tᵣ₂ is not equal to Tᵣ₁, and T_{c2} is not equal to T_{c1}.

14. The de-interleaving circuit according to claim 1, wherein a sequence according to which the memory stores the information units is different from a sequence according to which the memory outputs the information units.

15. A de-interleaving method, applied to a signal receiving device to perform a time de-interleaving process on an interleaved signal, a time interleaved block of the interleaved signal comprising a plurality of information units, the method comprising:
generating a plurality of writing addresses according to a predetermined rule;
generating a plurality of reading addresses according to the predetermined rule; and
storing the information units to a memory according to the writing addresses, and outputting the information units from the memory according to the reading addresses;
wherein, the information units are stored in a plurality of tiles, each of the tiles is a part or all of storage units of one row of the memory, a memory address associated with each of the tiles is different from a memory address associated with any other tile, the tiles correspond to a plurality of regions of the time interleaved block according to the predetermined rule, the regions comprise a first region and a second region, and in a same-row writing operation, a quantity of information units allowed to be successively written to each of the tiles in the first region is different from a quantity of information units allowed to be successively written to each of the tiles in the second region.

16. The method according to claim 15, wherein the information units are Nᵣ×N_{c} information units, where Nᵣ and N_{c} are positive integers, the regions comprise the first region, the second region and a third region, and in a same-row writing operation, a quantity of information units allowed to be successively written to each of the tiles in the third region is different from a quantity of information units allowed to be successively written to each of the tiles in the first region.

17. The method according to claim 15, wherein each of the tiles in the first region is Tᵣ×T_{c} storage units, each of the tiles in the second region is Tᵣ₁×T_{c1} storage units, a value of Tᵣ determines a quantity of information units allowed to be successively written to each of the tiles in the first region in a same-row writing operation, a value of T_{c} determines a quantity of information units allowed to be successively read from each of the tiles in the first region in a same-row reading operation, a value of Tᵣ₁ determines a quantity of information units allowed to be successively written to each of the tiles in the second region in a same-row writing operation, a value of T_{c1} determines a quantity of information units allowed to be successively read from each of the tiles in the second region in a same-row reading operation, Tᵣ₁ is not equal to Tᵣ, T_{c1} is not equal to T_{c}, Tᵣ multiplied by T_{c} is equal to Tᵣ₁ multiplied by T_{c1}, and Tᵣ, Tᵣ₁, T_{c} and T_{c1} are positive integers.

18. The method according to claim 17, wherein the regions comprise the first region, the second region and a third region, each of the tiles in the third region is Tᵣ₂×T_{c2} storage units, a value of Tᵣ₂ determines a quantity allowed to be successively written to each of the tiles in the third region in a same-row writing operation, a value of T_{c2} determines a quantity allowed to be successively read from each of the tiles in the third region in a same-row reading operation, Tᵣ₂ is not equal to Tᵣ, T_{c2} is not equal to T_{c}, Tᵣ multiplied by T_{c} is equal to Tᵣ₂ multiplied by T_{c2}, and Tᵣ₂ and T_{c2} are positive integers.

19. The method according to claim 18, wherein Tᵣ₂ is not equal to Tᵣ₁, and T_{c2} is not equal to T_{c1}.
